(19) United States
(12) Patent Application Publication
(10) Pub. No.: US 2005/0130432 A1
(43) Pub. Date: Jun. 16, 2005

(54) Method for improving transistor leakage current uniformity

(76) Inventor: Charles Frank Machala III, Plano, TX (US)

Correspondence Address: TEXAS INSTRUMENTS INCORPORATED, P O BOX 655474, M/S 3999, DALLAS, TX, 75265, US

(21) Appl. No.: 10/735,229

(22) Filed: Dec. 11, 2003

(51) Int. Cl. H01L 21/311

(52) U.S. Cl. 438/694

(57) ABSTRACT

Methods are described for fabricating semiconductor devices and transistors thereof, in which a patterned gate length is measured and offset spacers are formed along the sides of the patterned gate prior to drain extension implants, wherein the offset spacer width is controlled according to the measured gate length. This facilitates consistent control over transistor channel length despite variability in the patterned gate length dimension from wafer to wafer and/or from lot to lot.

### FIELD OF INVENTION

The present invention relates generally to semiconductor devices and more particularly to methods for fabricating transistors with improved leakage current uniformity.

### BACKGROUND OF THE INVENTION

Field effect transistors (FETs) are widely used in the electronics industry for switching, amplification, filtering, and other tasks related to both analog and digital electrical signals. Most common among these are metal-oxide-semiconductor field-effect transistors (MOSFETs), wherein a gate electrode is energized to create an electric field in a channel region of a silicon wafer or other semiconductor body, by which electrons are allowed to travel through the channel between source/drain regions outlying the channel in the semiconductor body. Complementary MOS (CMOS) devices have become widely used in the semiconductor industry, wherein both n-channel and p-channel (NMOS and PMOS) transistors are used to fabricate logic and other circuitry.

Continuing trends in semiconductor product manufacturing include reduction in electrical device feature sizes (scaling), as well as improvements in device performance in terms of device switching speed, drive current, and power consumption. MOS transistor performance may be improved by reducing the distance between the source and the drain regions under the gate electrode of the device, known as the gate or channel length, and by reducing the thickness of the layer of gate oxide that is formed over the semiconductor surface. However, scaled MOS transistors suffer from so-called short channel effects, wherein simply reducing the transistor channel length may degrade performance. Short channel effects include increased off-state (e.g., leakage) current, punch-through current, carrier drift velocity saturation, threshold voltage shifts, degraded subthreshold slope, and degraded output current.

Scaled MOS transistors may also suffer from channel hot carrier effects. For example, during saturation operation of a MOS transistor, electric fields are established near the lateral junction of the drain and channel regions. These fields causes channel electrons to gain kinetic energy and become “hot”. Some of these hot electrons traveling to the drain are injected into the thin gate dielectric proximate the drain junction. The injected hot carriers lead to undesired degradation of the MOS device operating parameters, such as a shift in threshold voltage, changed transconductance, and device instability.

To combat short channel and channel hot carrier effects, drain extension regions are commonly formed in the substrate, which are variously referred to as double diffused drains (DDD), lightly doped drains (LDD), moderately doped drains (MDD), and heavily doped drains (HDD). These relatively shallow drain extension regions absorb some of the potential into the drain and away from the drain/channel interface, thereby reducing channel hot carriers and the adverse performance degradation associated therewith.

During transistor fabrication, a gate dielectric, typically an oxide, is formed over the channel, and a gate electrode, typically polysilicon, is formed over the gate dielectric. The gate electrode is patterned to form a gate structure overlying the channel region of the substrate. The source and drain regions are typically formed by adding dopants to targeted regions of the semiconductor body on either side of the channel. The length of the channel between the transistor source and drain is largely determined by the length of the patterned gate structure. In a typical fabrication process, drain extension regions of the semiconductor body are implanted or doped after the gate is patterned, wherein the patterned gate acts as an implantation mask. After the drain extension implant, sidewall spacers are formed and deeper source/drain implants are performed to further define the transistor source/drain regions.

The off-state leakage current and on-state drive current performance of a MOS transistor are dependent upon the channel length of the device. Transistor leakage current includes subthreshold leakage, tunneling through the gate dielectric (e.g., gate leakage), source and drain diode leakage, and gate induced drain leakage. The metallurgical channel length affects the subthreshold leakage, which is the dominant leakage current mechanism of most MOSFET transistors. The subthreshold leakage current and the drive current increase as the channel length decreases, and the converse is true when the channel length increases. The drain extension implantation and subsequent thermal activation annealing result in the drain extension regions extending under the gate through lateral dopant diffusion, wherein the length of the channel region in the semiconductor body (e.g., the metallurgical channel length) is the lateral distance between the drain extension regions.

The gate is typically patterned by forming a photo-resist over the wafer (e.g., over the deposited polysilicon layer), and selectively exposing the resist to light using a photomask, sometimes referred to as photolithography. The exposure of the resist to light results in a chemical change to the exposed portions, after which either the exposed or the non-exposed portions are soluble, depending upon whether a positive or a negative resist is used. Subsequent cleaning results in removal of one or the other of the exposed or non-exposed resist, leaving a mask covering certain portions of the wafer and exposing other portions. An etch process is then performed, such as reactive ion etching (RIE) or other material removal process, wherein the exposed portions of the gate electrode polysilicon are removed, where the covered portions remain as a patterned gate structure.

As device dimensions are scaled to smaller and smaller values, the gate length dimension is typically at or near the process limitations of photolithography and etch processing. However, since the patterned gate length initially determines the location of the drain extension regions in the semiconductor body, process variations in the patterned gate length lead to variations in the device channel length. Such process variations can include, for example, variations in the photolithography processes used to expose the photoresist, reflection during the exposure process causing inadvertent exposure of more photoresist than was desired, variations in etch processes leading to uncontrollable variation in lateral etch rates, etc. Thus, conventional semiconductor manufacturing processes yield variations in transistor leakage current and drive current capability, where these parameters are often significantly different from wafer to wafer and from lot to lot. Accordingly, there is a need for improved semiconductor device fabrication techniques by which variations in leakage and drive current performance can be mitigated.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to the more detailed description that is presented later.

The present invention involves methods for fabricating semiconductor devices and transistors thereof, in which a patterned gate length critical dimension (CD) is measured for a given production wafer, and the measurement is used in forming offset spacers along the sides of the patterned gate prior to drain extension implants. In one implementation, the offset spacer widths are controlled such that the combined gate length plus the widths of two laterally opposite offset spacers is a constant, thereby facilitating uniformity in transistor channel lengths and the resulting transistor performance (e.g., uniform subthreshold leakage current and drive current capability) from wafer to wafer and from lot to lot. Thus, whereas other approaches attempt to limit gate CD variability, the present invention tolerates and compensates for such dimensional variations, thereby facilitating improved manufacturing yield.

In accordance with one aspect of the invention, a method is provided for fabricating a semiconductor device. The method comprises measuring a patterned gate length, and forming offset spacers along sides of a patterned gate structure, wherein a width of the offset spacers is determined according to the patterned gate length, before implanting drain extension regions of a semiconductor body. Measurement of the gate length can be by any suitable measurement technique, such as using a scanning electron microscope (SEM), atomic force microscope (AFM), or scatterometer. Moreover, any feature on a wafer may be measured, that has the same or similar feature size as the patterned gate length. For instance, a feature may be created in a scribe line region of a wafer having the same dimension as patterned gate structures in active regions of the wafer, where such a test structure is measured to determine the measured gate length.

The offset spacers may be made using any suitable materials and processes, such as conformally depositing and anisotropically etching a nitride or oxide material, by which offset spacers are created having a lateral width determined according to the gate length measurement. In an exemplary implementation presented below, one or both of the offset spacer material deposition thickness and/or the etch process parameters (e.g., etch time, chemistry, energy settings, etc.) may be controlled according to the patterned gate length measurement. In one example, the thickness of the deposited spacer material and/or the anisotropic etch process are controlled such that the offset spacer widths are about half the difference between a constant and the measured patterned gate length, where the constant is related to a desired metallurgical channel length.

In accordance with another aspect of the invention, a method is provided for fabricating a transistor, that comprises forming a gate dielectric layer above a semiconductor body, forming a gate electrode layer above the gate dielectric layer, and selectively etching the gate electrode layer to form a patterned gate structure. The method further includes measuring the length of the patterned gate, determining an offset distance based on the measured patterned gate length, and forming offset spacers along laterally opposite sides of the patterned gate structure, where the offset spacers extend laterally outwardly from the patterned gate structure by the offset distance. Thereafter, a drain extension implant is performed with the offset spacers along the laterally opposite sides of the patterned gate structure to provide dopants to drain extension portions of the semiconductor body. The offset distance in one implementation is about half the difference between a constant and the measured patterned gate length, wherein the constant is related to a desired metallurgical channel length.

The following description and annexed drawings set forth in detail certain illustrative aspects and implementations of the invention. These are indicative of only a few of the various ways in which the principles of the invention may be employed.

### BRIEF DESCRIPTION OF THE DRAWINGS

FIG. 1 is a flow diagram illustrating an exemplary method of fabricating a transistor in a semiconductor device in accordance with one or more aspects of the present invention;

FIGS. 2A-2I are partial side elevation views in section illustrating an exemplary semiconductor device undergoing fabrication processing in which variable width offset spacers are formed according to a measured gate length in accordance with the invention; and

FIGS. 3-5 are partial side elevation views in section illustrating semiconductor devices with varying gate length dimensions, wherein variable width offset spacers are formed according to a measured gate length in accordance with the invention.

### DETAILED DESCRIPTION OF THE INVENTION

One or more implementations of the present invention will now be described with reference to the attached drawings, wherein like reference numerals are used to refer to like elements throughout. The invention relates to semiconductor devices formed using variable width offset spacers according to a measured gate length. The invention is hereinafter illustrated and described with respect to several exemplary methods and semiconductor devices, in which exemplary PMOS transistors are formed in a silicon wafer. However, the invention may be employed, alternatively or in combination, in fabricating NMOS transistors and devices formed using any type of semiconductor body (e.g., semiconductor wafers, SOI wafers, etc.), wherein the invention is not limited to the illustrated examples, and wherein the illustrated structures are not necessarily drawn to scale.

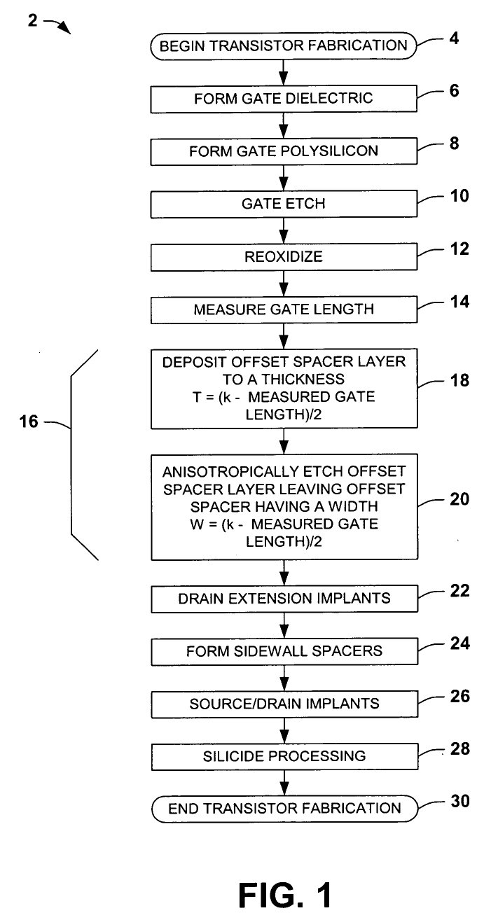

Referring initially to FIG. 1, an exemplary method 2 is illustrated for fabricating transistors wherein a patterned gate length is measured and offset spacers are formed along the sides of the patterned gate prior to drain extension implants, and wherein the offset spacer width is set according to the measured gate length. This facilitates consistent control over transistor channel length regardless of variation in the patterned gate length dimension from wafer to wafer and/or from lot to lot. Although the method 2 is illustrated and described below as a series of acts or events, it will be appreciated that the present invention is not limited by the illustrated ordering of such acts or events. For example, some acts may occur in different orders and/or concurrently with other acts or events apart from those illustrated and/or described herein, in accordance with the invention. In addition, not all illustrated steps may be required to implement a methodology in accordance with the present invention. The methods according to the present invention, moreover, may be implemented in association with the fabrication of devices illustrated and described herein as well as in association with other devices and structures not illustrated.

Transistor fabrication begins at 4, wherein a gate dielectric is formed over a semiconductor body at 6 using any suitable materials, material thicknesses, and processing steps, including a single thermal oxidation or deposition or combinations thereof to form a gate dielectric above a semiconductor body. The invention may be employed in fabricating semiconductor devices using any type of semiconductor body, including but not limited to silicon substrates, partially and fully depleted SOI wafers, wafers having virtual substrates (e.g., thick or thin SiGe or GaAs layers and/or InGaAs graded layers formed on silicon substrates, substrates in which transistor channels extend vertically, etc.). In addition, the invention may be employed in conjunction with any gate dielectric material, such as SiO₂, SiON, high-k dielectrics, and stacks or combinations thereof, and separate processing may optionally be employed to form different gate dielectrics form NMOS and PMOS devices within the scope of the invention. In the exemplary devices illustrated and described below, a single thermal oxidation is performed at 6 to create a thin silicon dioxide (SiO₂) gate oxide (e.g., a few monolayers up to several hundred Å thick) overlying a silicon substrate.

At 8, a gate electrode layer is formed above the gate dielectric layer, for example, by depositing a layer of polysilicon to any desired thickness (e.g., depositing several thousand A of polysilicon using chemical vapor deposition (CVD) in one possible implementation). The present invention may be employed in association with any gate electrode material or materials, including single and multi-layer structures, which may include polysilicon doped before and/or after patterning at 10, and the gate electrode may comprise one or more metals. In the exemplary implementation, the polysilicon gate electrode layer is then selectively patterned at 10 to define a patterned gate structure, for example, using an etch mask and a reactive ion etch (RIE) process or other suitable patterning techniques. As a result of the gate etch at 10, a portion of the semiconductor body (e.g., or the gate dielectric) is exposed in prospective source/drain and drain extension regions, leaving a patterned gate structure having a gate length.

At 12, an oxidation (e.g., reoxidation) process is performed to oxidize a surface portion of the patterned gate structure as well as the exposed semiconductor body (e.g., drain extensions and source/drains). In the exemplary implementation with a polysilicon gate, this reoxidation at 12 creates a silicon dioxide (e.g., SiO₂) having a thickness of about 60 Å overlying the top and sidewalls of the gate structure as well as the exposed semiconductor body. Any suitable oxidation processing may be undertaking at 16 in accordance with the invention, for example, exposing the wafer to an oxidizing ambient at elevated temperature (e.g., thermal oxidation process). In this example, the oxide created at 12 operates as an etch-stop material during subsequent formation of nitride offset spacers at 20 below.

In accordance with an aspect of the invention, a gate length is measured at 14. Although illustrated in the method 2 as occurring after the reoxidation at 12, the gate length measurement at 14 can alternatively be performed prior to reoxidation at 12 or the reoxidation 12 can be omitted. Any suitable feature measurement techniques and/or equipment may be employed to measure or estimate the gate length dimension at 14. For example, the patterned gate length may be measured at 14 via scanning electron microscopy, atomic force microscopy, scatterometry, or other techniques.

In addition, the measurement may be made of a particular patterned gate structure in active regions of a wafer being processed, or a test gate structure (e.g., dummy gate) may be formed in a non-essential region of the wafer (e.g., in a scribe line region) for use in determining or estimating the gate lengths of gate structures throughout the wafer. In this case, the test structure can be a polysilicon line or other structure having a feature size or dimension corresponding to (e.g., formed in the same manner as) gate lengths in active regions of the wafer, whereby a measurement of the test structure dimension can be correlated to patterned gate lengths in the wafer generally. In this regard, the use of a scribe line structure can facilitate measurement of patterned gate length dimensions in production wafers without measurement related damage to active circuits (e.g., such as using scanning electron microscopy (SEM), wherein the portion of the wafer including the test feature is coated with a conductive film for measurement). The measurement at 14 can include any or all such preparation steps needed to measure the gate length dimension.

In addition, a single dimension may be measured on a given wafer, or multiple features may be measured, wherein averaging or other data analysis may be performed on such multiple measurement values in determining the offset spacer width within the scope of the invention. Moreover, the measurement at 14 may be performed in a separate system, or may be performed in situ within an etch chamber used for the gate etch at 12, or within a deposition chamber used for subsequent deposition of the offset spacer material at 18.

Once the measurement is made at 14, offset spacers are formed at 16 along sides of a patterned gate structure prior to implanting drain extension regions of the semiconductor body at 22, wherein the lateral extension of the offset spacers (e.g., offset spacer widths) is determined or set according to the measured gate length dimension. The offset spacers may be formed at 16 using any suitable processing step or steps in accordance with the invention. In addition, the offset spacers may be formed at 16 using any materials within the scope of the invention.

In the illustrated example, an offset spacer material layer is deposited at 18 over the top and sides of the patterned gate structure and above prospective source/drain regions of the semiconductor body using chemical vapor deposition (CVD), where the deposition thickness is determined according to the patterned gate length. In this implementation, the offset spacer material comprises silicon nitride (e.g., Si₃N₄), although silicon oxides or other materials may be used. In this case, conformal spacer material deposition at 18, and the subsequent anisotropic etching at 20, provides offset spacers along the patterned gate sides having widths generally equal to the deposition thickness. Thus, the deposition thickness is largely driven by the measured patterned gate length, wherein the spacer material is deposited at 18 to about half the difference between a constant “k” and the measured patterned gate length (e.g., deposition thickness=0.5*[k−measured patterned gate length], where the constant k is related to a desired metallurgical channel length dimension).

An etch process is performed at 20, for example, an anisotropic etch process that removes portions of the offset spacer material from prospective drain extension regions of the semiconductor body and leaves offset spacer material along the sides of the patterned gate structure. The etching at 20 may be controlled to achieve a final offset spacer width determined according to the measured gate length, alone or in combination with controlling the deposition thickness at 18. In this regard, the etching at 20 may be terminated when the offset spacer width is more than, less than, or equal to the original deposition thickness. Further, the resulting offset spacers may, but need not extend vertically along the entire side of the patterned gate (e.g., wherein any optional oxide created at 12 above is considered as part of the patterned gate structure). In the illustrated example, the reoxidation at 12 provides a thin layer of SiO₂, over which the Si₃N₄ spacer layer material is deposited at 18. During subsequent etching at 20, the underlying oxide acts as an etch-stop layer, wherein the etch process is preferably selective to the oxide. In this regard, an anisotropic etch is preferable, where conformally deposited Si₃N₄ will be etched from the top of the patterned gate and from the substrate at a much higher rate than from the sidewalls of the patterned gate structure.

In the exemplary method 2, an anisotropic reactive ion etch (RIE) process is performed at 20, which may be controlled according to the measured patterned gate length (e.g., etch duration, etch chemistry, energy settings, etc.). For example, the etching at 20 can be controlled such that the final width of the offset spacers is about half the difference between a constant and the measured patterned gate length (e.g., 0.5*[k−measured patterned gate length]. Thus, one or both of the deposition at 18 and etching at 20 may be controlled to yield offset spacers that provide for consistent drain extension implants at 22, where the channel length can be made generally uniform from wafer to wafer and from lot to lot, even in the presence of variations in patterned gate lengths.

After forming the offset spacers at 16, drain extension regions of the semiconductor body are implanted at 22, wherein suitable activation annealing can also be performed. Such thermal operations may cause the implanted drain extension dopants to diffuse downward and laterally from the originally implanted locations. However, it is noted that such post implantation thermal processing and the associated dopant diffusion will generally be the same from wafer to wafer and from lot to lot, wherein the provision of variable width spacers at 16 provides uniformity in the initial channel length (e.g., the initial distance between implanted drain extension regions of the semiconductor body).

Sidewall spacers are then formed at 24 along the sides of the patterned gate (e.g., extending laterally outwardly from the offset spacers), which may be formed using any suitable processing techniques and materials within the scope of the invention, such as through deposition and etching of one or more nitride or oxide materials, or stacks or combinations thereof. In one example, the sidewall spacers may be multilayer structures comprising first and second oxide layers with a nitride layer therebetween. Deep source/drain implants are then performed at 26 to further define source/drain regions of the semiconductor body, and silicide processing is performed at 28 to provide conductive contacts over the source/drains and the top of the polysilicon gate electrode, whereafter the transistor fabrication of the method 2 ends at 30. Interconnect and other back-end processing (not shown) can then be performed to complete a finished semiconductor device.

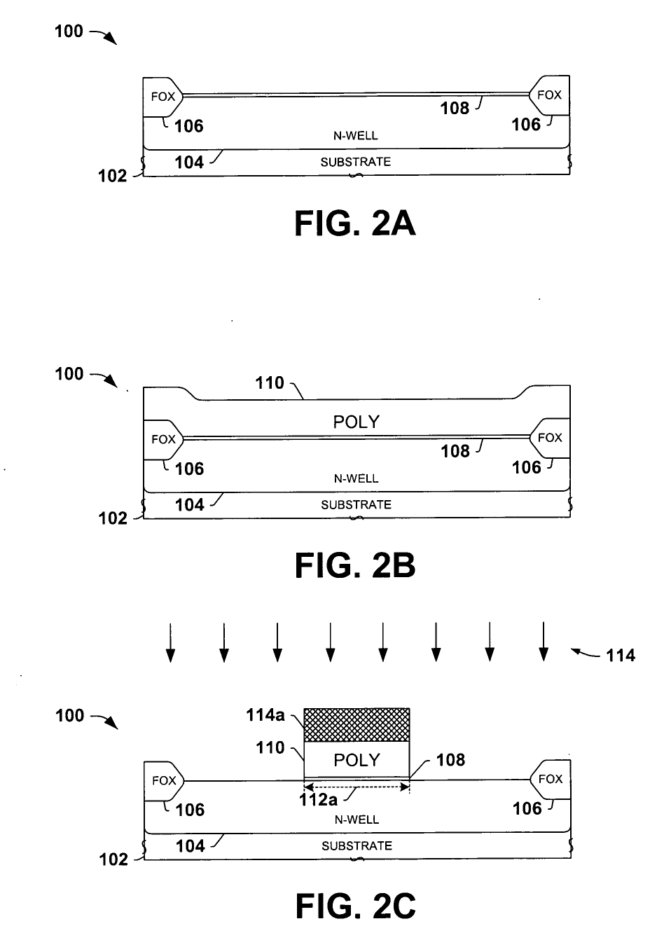

FIGS. 2A-2I illustrate an exemplary semiconductor device 100 undergoing fabrication processing generally in accordance with the above method 2, wherein an exemplary PMOS transistor is illustrated, although the invention may be employed in fabricating NMOS transistors as well. The device 100 comprises a silicon wafer semiconductor body 102 with an n-well 104 formed in a PMOS region thereof, as well as field oxide (FOX) isolation structures 106 formed by local oxidation of silicon (LOCOS). Other isolation structures 106 may alternatively be constructed, for example, using shallow trench isolation (STI) techniques. In FIG. 2A, a gate dielectric 108 is formed (e.g., at 6 in the method 2 of FIG. 1 above) over the surface of the substrate 102 between the isolation structures 106. In the illustrated device 100, the gate dielectric 108 is a thermally grown SiO₂, although any suitable dielectric may be formed within the scope of the invention, including single or multi-layer dielectric structures, for example, comprising high-k dielectric materials.

In FIG. 2B, polysilicon 110 is formed over the gate dielectric 108 (at 8 in FIG. 1), to operate as a gate electrode material layer in a subsequently patterned gate structure. In FIG. 2C, the polysilicon layer 110 is selectively patterned (gate etch 10 in FIG. 1) to define a patterned gate structure having a patterned gate length 112a. The gate is patterned via an etch process 114 (e.g., RIE or other etching process) using an etch mask 114a. In FIG. 2D, the top and sidewalls of the patterned polysilicon 110 and the exposed substrate 102 are oxidized (12 in FIG. 1) via an oxidation process 116 to form a protective oxide encapsulation layer 118 thereon. Whereas the patterned polysilicon gate length 112a (FIG. 2C) may be several thousand Å in certain examples, the protective oxide layer 118 is much thinner (e.g., about 60 Å in one example), wherein the patterned gate structure now has a length 112b as shown in FIG. 2D, including the encapsulation layer 118.

At this point, (e.g., or prior to the reoxidation), the gate length 112b is measured (e.g., 14 in FIG. 1), using any suitable feature measurement techniques and/or equipment, such as scanning electron microscopy, atomic force microscopy, scatterometry, or other techniques. In FIGS. 2E and 2F, offset spacers 120 are formed along lateral sides of the patterned gate structure to a width 120a determined according to the patterned gate length 112b. As in the above method 2, the spacers 120 are formed by a two-step process, including a conformal deposition process 122 (e.g., CVD) to form Si₃N₄ spacer layer material 120 to a deposition thickness 120a of about 0.5*[k−measured patterned gate length 112b], where the constant k can be related to a desired metallurgical channel length dimension. For example, where the desired channel width k is 2000 Å, and the actual measured gate length is 1740 Å, the Si₃N₄ spacer layer material 120 is deposited to a thickness 120a of (2000−1740)/2=130 Å.

The deposited nitride 120 is then anisotropically etched in FIG. 2F via an RIE etch process 124 that is selective to the oxide 118, and which removes portions of the offset spacer material 120 from prospective drain extension regions of the semiconductor body 102 and leaves offset spacer material 120 along the oxidized sides of the patterned gate structure. The deposition process 122 of FIG. 2E and/or the etch process 124 of FIG. 2F are tailored to provide the finished offset spacers 120 having widths 120a determined according to the measured gate length 112b (FIG. 2D). The offset spacers 120 may, but need not, extend to the top of the gate sidewalls, for example, wherein the etch process 124 may be continued to the point where the offset spacers 120 extend only part way up the patterned gate sidewalls, in order to provide the finished spacers 120 having a width 120a determined by the measured gate length 112b.

With the finished offset spacers 120 in place, a shallow drain extension implant 126 is performed in FIG. 2G (e.g., LDD, MDD, or HDD implant at 22 in FIG. 1), to introduce dopants (e.g., boron or other p-type impurities in the illustrated PMOS example) into the exposed source/drain regions 128 of the semiconductor body 102. The device 100 may be annealed (not shown) to activate and slightly diffuse the implanted dopants downward and laterally, wherein the separation between the implanted drain extension regions 128 defines a channel length 128a, as shown in FIG. 2G that is related to the constant k (FIGS. 2E and 2F). Although the exemplary channel length 128a is generally illustrated in FIG. 2G as being the same as the constant k of FIG. 2F, the implantation process 126 may be performed at a slight angle and/or thermal processing may cause the channel length 128a to be smaller than the gate length 112b. All such relationships between the constant k and the resulting channel length are contemplated as falling within the scope of the invention.

Referring now to FIG. 2H, after the drain extension implants, sidewall spacers 130 are formed (24 in FIG. 1) along the sidewalls of the patterned gate structure (e.g., extending laterally outward from the offset spacers 120), where the sidewall spacers 130 can include any suitable oxide and/or nitride material or stacks or combinations thereof. A deep source/drain boron implant 132 is then performed (26 in FIG. 1) to further define the source/drains 128. In FIG. 21, silicide contacts 136 are formed via a silicide process 134 (28 in FIG. 1) over the source/drains 128 and the polysilicon gate electrode 110, after which interconnect and other back-end processing (not shown) is performed to complete the device 100.

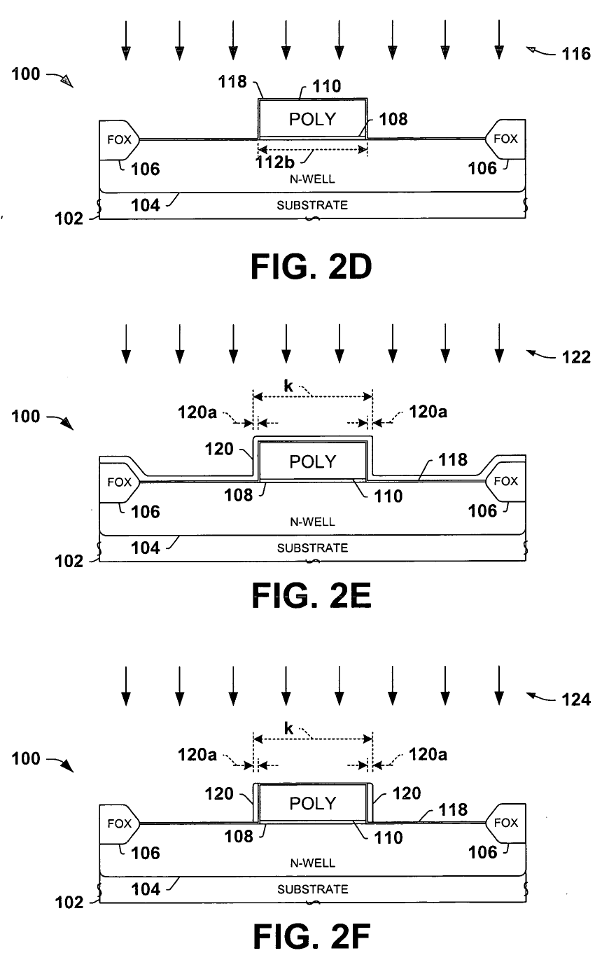

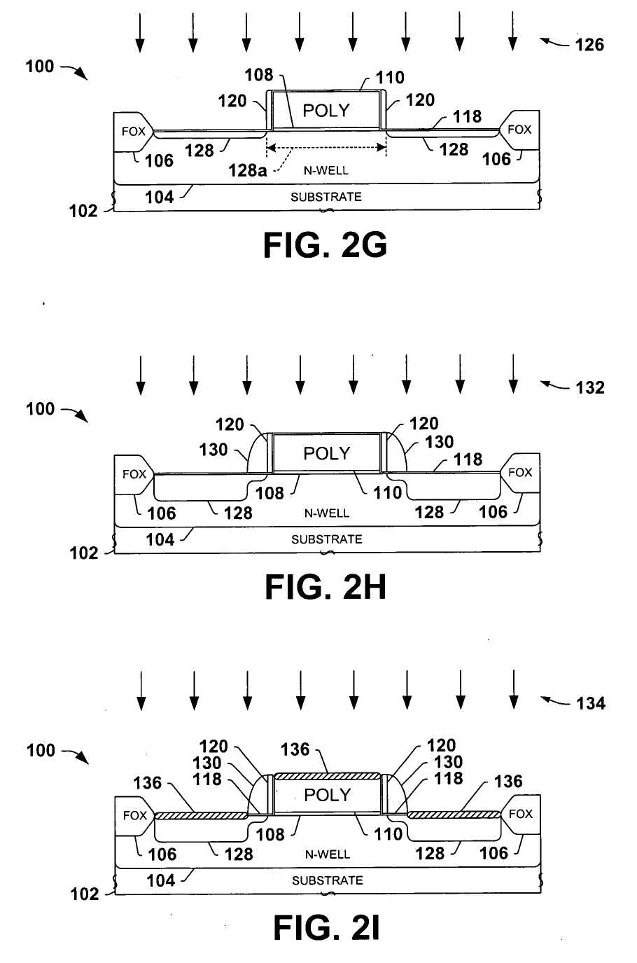

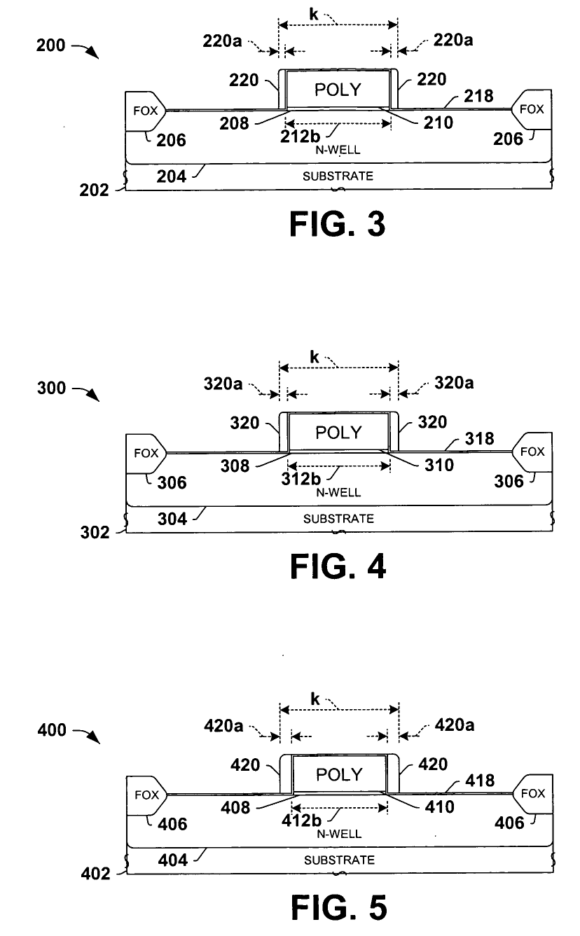

FIGS. 3-5 illustrate semiconductor devices 200, 300, and 400, respectively, having varying patterned gate length dimensions, wherein variable width offset spacers are formed according to a measured gate length in accordance with the invention to achieve uniform channel lengths despite variation in patterned gate lengths. FIG. 3 illustrates the device 200 comprising a semiconductor body 202 in which an n-well 204 is formed, wherein a patterned gate structure is being fabricated for a PMOS transistor between isolation structures 206. The gate structure includes a gate oxide 208 and an overlying patterned polysilicon gate electrode 210, with an oxide encapsulation layer 218 formed thereover. In FIG. 4, a device 300 comprises a semiconductor body 302 with an n-well 304 and a patterned gate structure comprising a gate oxide 308 and a patterned polysilicon gate electrode 310, with an oxide encapsulation layer 318. The device 400 in FIG. 5 comprises a semiconductor body 402, an n-well 404, a patterned gate structure with a gate oxide 408 and a gate electrode 410, as well as an oxide encapsulation layer 418.

The patterned gate structure of the device 200 in FIG. 3 has a length 212b slightly smaller than that of the device 100 (e.g., FIG. 2D above). In accordance with the present invention, however, offset spacers 220 are formed along the gate sides, having widths 220a determined by the measured gate length 212b. Using this approach, the measured gate length 212b plus two times the offset spacer width 220a equals the constant k (e.g., where k may represent a desired channel length for all the devices 100, 200, 300, and 400). In this manner, the variation in the gate lengths 112b and 212b is compensated for by the difference in the offset spacer widths 120a and 220a. Similarly, in FIG. 4, the patterned gate length 312b is less than the first two gate lengths 112b or 212b, wherein offset spacers 320 are constructed having still larger widths 320a. Yet another example is illustrated in the device 400 of FIG. 5, wherein a still smaller patterned gate length 412b is compensated for by forming wider offset spacers 420 having widths 420a.

Thus, the invention facilitates uniform metallurgical channel lengths by providing variable-width offset spacers at the time when drain extension implants are performed, whereby the uniformity of channel lengths can be enhanced from wafer to wafer and from lot to lot, even where the patterned gate length dimensions are changing. This, in turn, can improve uniformity of transistor device performance specifications from wafer to wafer and lot to lot, for example, including more uniform leakage current and drive current values, compared with conventional manufacturing techniques. Although illustrated and described above in the context of a single wafer, the invention may be employed for each wafer in a fabrication operation, or alternatively may be employed on less than every wafer. For instance, the gate length measurements and any corresponding adjustments to the offset spacer fabrication (e.g., deposition and/or etch parameter adjustments) may be done for every Nth wafer where N is an integer greater than 1, or once for each production lot, or periodically such as once a day, or according to any desired routine. Thus, statistical process control (SPC) algorithms may be employed where the sampling frequency increases after a significant patterned gate length change is detected, or where the sampling frequency decreases over time as the process stabilizes, wherein the invention and the appended claims are not limited to any particular employment strategy.

Although the invention has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising”.

1. A method of fabricating a semiconductor device, the method comprising:
measuring a patterned gate length of a patterned gate structure;
forming offset spacers along sides of the patterned gate structure, wherein a width of the offset spacers is determined according to the patterned gate length; and
implanting drain extension regions of a semiconductor body after forming the offset spacers.

2. The method of claim 1, wherein forming the offset spacers comprises:
conformally depositing an offset spacer material layer over the top and sides of the patterned gate structure and above prospective source/drain regions of the semiconductor body; and
performing an anisotropic etch process that removes portions of the offset spacer material from prospective drain extension regions of the semiconductor body and leaves offset spacer material along the sides of the patterned gate structure.

3. The method of claim 2, wherein the offset spacer material comprises silicon nitride or silicon oxide.

4. The method of claim 2, Wherein the offset spacer material comprises silicon nitride, further comprising forming an oxide over the patterned gate structure and over the prospective drain extension regions of the semiconductor body prior to conformally depositing the offset spacer material layer.

5. The method of claim 2, wherein the offset spacer material layer is deposited to a thickness determined according to the patterned gate length.

6. The method of claim 5, wherein the thickness of the deposited spacer material is about half the difference between a constant and the measured patterned gate length.

7. The method of claim 6, wherein the constant is related to a desired channel length.

8. The method of claim 5, wherein the anisotropic etch process is controlled according to the measured patterned gate length.

9. The method of claim 8, wherein the thickness of the deposited spacer material and the anisotropic etch process are controlled so that the width of the offset spacers is about half the difference between a constant and the measured patterned gate length.

10. The method of claim 9, wherein the constant is related to a desired channel length.

11. The method of claim 2, wherein the anisotropic etch process is controlled according to the measured patterned gate length.

12. The method of claim 11, wherein the anisotropic etch process is controlled so that the width of the offset spacers is about half the difference between a constant and the measured patterned gate length.

13. The method of claim 12, wherein the constant is related to a desired channel length.

14. The method of claim 2, wherein the thickness of the deposited spacer material and the anisotropic etch process are controlled so that the width of the offset spacers is about half the difference between a constant and the measured patterned gate length.

15. The method of claim 14, wherein the constant is related to a desired channel length.

16. The method of claim 1, wherein the width of the offset spacers is about half the difference between a constant and the measured patterned gate length.

17. The method of claim 16, wherein the constant is related to a desired channel length.

18. The method of claim 1, wherein the offset spacers comprise silicon nitride or silicon oxide.

19. The method of claim 1, wherein measuring the patterned gate length comprises one of scanning electron microscopy, atomic force microscopy, and scatterometry.

20. The method of claim 1, wherein measuring the patterned gate length comprises measuring a dimension of a patterned test structure in a scribe line region of a wafer.

21. A method of fabricating a transistor, the method comprising:
forming a gate dielectric layer above a semiconductor body;
forming a gate electrode layer above the gate dielectric layer;
selectively etching the gate electrode layer to form a patterned gate structure having a patterned gate length;
measuring the patterned gate length;
determining an offset distance based on the measured patterned gate length;
forming offset spacers along laterally opposite sides of the patterned gate structure, the offset spacers extending laterally outwardly from the patterned gate structure by the offset distance; and
performing a drain extension implant with the offset spacers along the laterally opposite sides of the patterned gate structure to provide dopants to drain extension portions of the semiconductor body.

22. The method of claim 21, wherein the offset distance is about half the difference between a constant and the measured patterned gate length.

23. The method of claim 22, wherein the constant is related to a desired channel length.

24. A method of fabricating a semiconductor device, the method comprising:
forming a gate dielectric layer above a semiconductor body;
forming a gate electrode layer above the gate dielectric layer;
selectively etching the gate electrode layer to form a patterned gate structure having a patterned gate length;
measuring a patterned gate length;
forming offset spacers along sides of a patterned gate structure, wherein a width of the offset spacers is determined according to the patterned gate length; and
implanting drain extension regions of a semiconductor body after forming the offset spacers.

25. The method of claim 24, wherein the width of the offset spacers is about half the difference between a constant and the measured patterned gate length.

26. The method of claim 25, wherein the constant is related to a desired channel length.
